(19) United States
(12) Patent Application Publication
(10) Pub. No.: US 2024/0103070 A1
(43) Pub. Date: Mar. 28, 2024

(54) SEMICONDUCTOR DEVICE AND SEMICONDUCTOR PACKAGE INCLUDING THE SAME

(71) Applicant: Samsung Electronics Co., Ltd., Suwon-si (KR)

(72) Inventors: Yeonjin Lee, Suwon-si (KR); Jongmin Lee, Suwon-si (KR)

(21) Appl. No.: 18/230,373

(22) Filed: Aug. 4, 2023

(30) Foreign Application Priority Data
Sep. 27, 2022 (KR) 10-2022-0122872

(51) Int. Cl. G01R 31/28; H01L 21/66

(52) U.S. Cl. CPC G01R 31/2884; H01L 22/32

(57) ABSTRACT

Provided is a semiconductor device including a substrate including an element region and a scribe lane region defining the element region, and one or more test element groups arranged on the substrate and including one or more test elements for characteristic evaluation and one or more test pads for applying a test signal for testing the one or more test elements, wherein all of the one or more test pads are spaced apart from the element region in a horizontal direction.

### CROSS-REFERENCE TO RELATED APPLICATION

This application is based on and claims priority under 35 U.S.C. § 119 to Korean Patent Application No. 10-2022-0122872, filed on Sep. 27, 2022, in the Korean Intellectual Property Office, the disclosure of which is incorporated by reference herein in its entirety.

### BACKGROUND

Aspects of the inventive concept relate to a semiconductor device and a semiconductor package including the same, and more particularly, to a semiconductor device including a test pad and a semiconductor package including the semiconductor device.

A semiconductor device, as described herein, may refer to a semiconductor chip or semiconductor package, or may refer to a group of semiconductor chips, for example formed on a wafer prior to being separated. In a conventional semiconductor device in which many unit semiconductor chips are integrated, the unit semiconductor chips may be arranged in an array, separated by scribe lanes formed between each unit semiconductor chip, a characteristic evaluation element for an individual transistor element or the like may be formed on each unit semiconductor chip, and one or more test pads for applying a test signal to test the characteristic evaluation element are included in a chip region. Additional test pads and test circuits may be included in the scribe lane region. Each semiconductor chip may be separated while being sawed along the scribe lane region.

In general, semiconductor devices formed on semiconductor substrates such as silicon are manufactured through a series of unit processes including a lamination process of layers, a doping process of impurities, a photolithography process for patterning of these layers, and an etching process. To determine whether each unit process has been accurately performed to suit a design, it is possible to use test circuits and test pads to detect defects in semiconductor devices manufactured at the end of each unit process, such as transistors, capacitors, resistors, and inductors, or evaluate the parameter characteristics of these devices.

### SUMMARY

Aspects of the inventive concept provide a semiconductor device having improved reliability and a semiconductor package including the same.

Aspects of the inventive concept provides a semiconductor device having reduced process operations and a semiconductor package including the same.

According to an aspect of the inventive concept, a semiconductor device includes a substrate including an element region and a scribe lane region defining and surrounding the element region, and one or more test circuits arranged on the substrate and including one or more test elements for characteristic evaluation and one or more test pads for applying a test signal for testing the one or more test elements, wherein all of the one or more test pads are spaced apart from the element region in a horizontal direction.

According to another aspect of the inventive concept, a semiconductor device includes a substrate including an element region and a scribe lane region defining and surrounding the element region, and one or more test element circuits arranged on the substrate and including one or more test elements for characteristic evaluation and one or more first test pads electrically connected to first test elements of the one or more test elements and for applying a test signal for testing the one or more test elements, wherein all of the one or more first test pads are arranged in a pad region outside of the element region in a horizontal direction, the one or more test elements include one or more first test elements arranged in the scribe lane region and one or more second test elements arranged in the element region, the one or more test element circuits further include one or more second pads arranged in the element region and electrically connected to the one or more respective second test elements, the one or more second pads are formed at the same vertical height as the one or more first test pads, and in a first horizontal direction at least one edge of each of the one or more first test pads are longer than the length of each edge of each of the one or more second pads.

According to another aspect of the inventive concept, a semiconductor package includes an interposer, a first semiconductor chip arranged on the interposer and including an element region and a scribe lane region defining and surrounding the element region, a plurality of second semiconductor chips sequentially stacked on the first semiconductor chip, a molding layer surrounding the plurality of second semiconductor chips on the first semiconductor chip, and one or more test element groups arranged on the first semiconductor chip and including one or more test elements for characteristic evaluation and one or more test pads for applying a test signal for testing the one or more test elements. All of the one or more test pads are spaced apart from the element region in a horizontal direction.

### BRIEF DESCRIPTION OF THE DRAWINGS

Embodiments of the inventive concept will be more clearly understood from the following detailed description taken in conjunction with the accompanying drawings in which:

FIG. 1 is a plan layout of a semiconductor device including a test element group according to an embodiment;

FIG. 2A is an enlarged plan layout of a portion indicated by “II” of FIG. 1 according to an embodiment;

FIG. 2B is an enlarged plan layout of a portion indicated by “III” of FIG. 1 according to an embodiment;

FIG. 3 is a plan layout of a semiconductor device including a test element group according to an embodiment;

FIG. 4 is an enlarged plan layout of a portion indicated by “IV” of FIG. 3 according to an embodiment;

FIG. 5 is a plan layout of a semiconductor device including a test element group according to an embodiment;

FIG. 6 is an enlarged plan layout of a portion VI of FIG. 5 according to an embodiment; and

FIG. 7 is a cross-sectional view of a semiconductor package according to an embodiment.

### DETAILED DESCRIPTION OF THE EMBODIMENTS

Hereinafter, embodiments of the inventive concept will be described in detail with reference to the accompanying drawings. The same reference numerals are used for the same components in the drawings, and redundant descriptions thereof will be omitted.

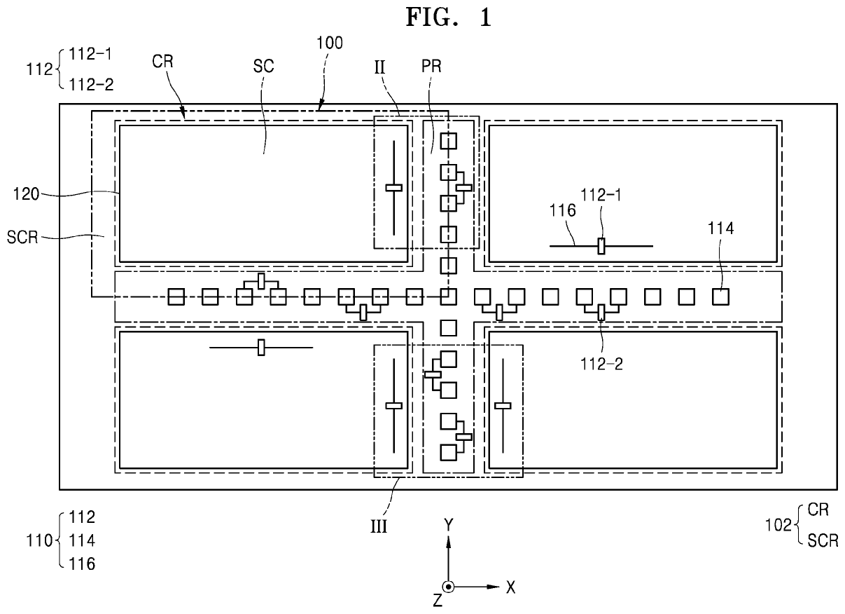

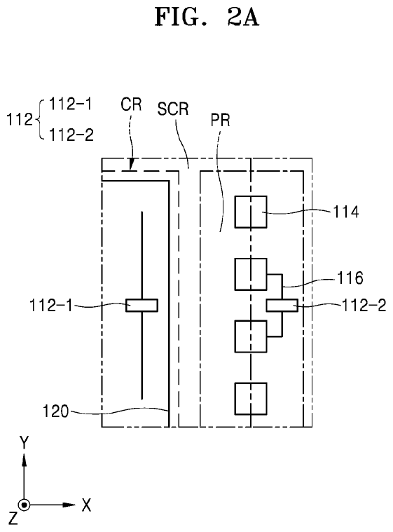

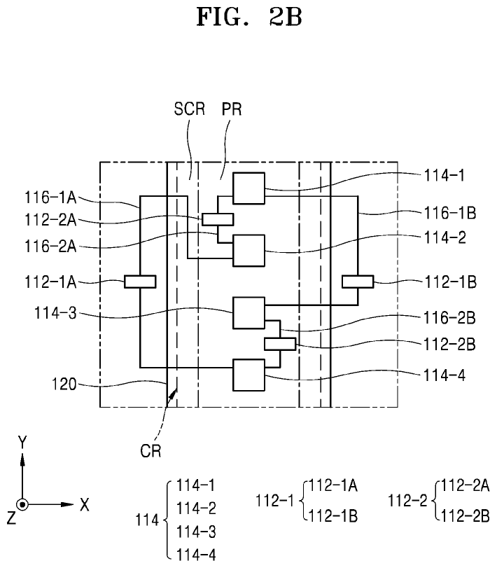

FIG. 1 is a plan layout of a semiconductor device including a test element group according to an embodiment. FIG. 2A is an enlarged plan layout of a portion II of FIG. 1 according to an embodiment, and FIG. 2B is an enlarged plan layout of a portion III of FIG. 1 according to an embodiment.

Referring to FIGS. 1 and 2A, a semiconductor device 100 may include a test element group 110 and a guard ring 120, which are arranged on a substrate 102.

The substrate 102 includes element regions CR (also described as chip regions) and scribe lane regions SCR. The scribe lane regions SCR are part of the scribe lane formed between element regions CR on a semiconductor substrate such as a wafer. The scribe lane regions SCR remain on the individualized devices (e.g., chips) after singulation, and for each device, may be arranged along the edge of the substrate 102 to surround the element region CR. Accordingly, the scribe lane region SCR may define the element region CR. For example, scribe lanes may be formed between semiconductor devices (e.g., between semiconductor chips) formed in an array pattern on a wafer, and when the semiconductor devices are singulated from each other (e.g., cut), they may be cut along the scribe lanes, and portions of the scribe lanes may remain on the singulated semiconductor devices to form the scribe lane regions SCR.

The substrate 102 may include or be formed of silicon (Si). Alternatively, the substrate 102 may include or be formed of a semiconductor material such as germanium (Ge), or compound semiconductors such as silicon carbide (SiC), gallium arsenide (GaAs), indium arsenide (InAs), and indium phosphide (InP). The substrate 102 may have an active surface and an inactive surface opposite to the active surface. A semiconductor device including various types of individual devices may be formed on the active surface of the substrate 102. The plurality of individual devices may include various microelectronic devices such as a metal-oxide-semiconductor field effect transistor (MOSFET) such as a complementary metal-insulator-semiconductor (CMOS) transistor, an image sensor such as a large scale integration (LSI), a CMOS imaging sensor (CIS), etc., a micro-electro-mechanical system (MEMS), an active device, a passive device, etc.

The plurality of individual devices may be electrically connected to a conductive region of the substrate 102. The conductive region may refer to a region including connection terminals or other conductive elements for communicating between the individual devices and another semiconductor device. The semiconductor device may further include at least two different types of the plurality of individual devices, and may include a conductive wiring or a conductive plug electrically connecting the plurality of individual devices with the conductive region of the substrate 102. In addition, the plurality of individual devices may be electrically separated from other neighboring individual devices by insulating layers, respectively.

The substrate 102, prior to singulation, may include one or more semiconductor chips SC. Although FIG. 1 illustrates that one substrate 102 includes four semiconductor chips SC, the present disclosure is not limited thereto. For example, prior to singulation one substrate 102 may include three or less semiconductor chips SC, or five or more semiconductor chips SC. Therefore, after singulation, a scribe lane region SCR may surround an element region of each single semiconductor chip SC.

The semiconductor chip SC may be, for example, a central processing unit (CPU) chip, a graphics processing unit (GPU) chip, or an application processor (AP) chip. The semiconductor chip SC is, for example, a dynamic random access memory (DRAM) chip, a static random access memory (SRAM) chip, a flash memory chip, an electrically erasable and programmable read-only memory (EEPROM) chip, a phase-change random access memory (PRAM) chip, a magnetic random access memory (MRAM) chip, or a resistive random access memory (RRAM) chip.

The test element group 110 may be a pattern, or circuit (e.g., test circuit), for testing a manufacturing process of a semiconductor device and characteristics of the completely manufactured semiconductor device, for example, prior to singulation of the semiconductor device from the wafer. The test element group 110 may include a plurality of test elements 112, a plurality of test pads 114, and a plurality of test wirings 116. In some embodiments, a plurality of test elements 112 may constitute one test element group module (not shown), and the test element group module may constitute one test element group 110.

For example, the test element 112 may be an MOS transistor having source/drains and a gate. For example, the test element 112 may be a P-channel transistor, an N-channel transistor, a field N-channel transistor, a field P-channel transistor, a capacitor, a contact chain, and/or a resistor. For example, a test element 112 may be arranged in the element region CR and/or the scribe lane region SCR. A test element 112 arranged in the element region CR of the plurality of test elements 112 may be referred to as a first test element 112-1, or a chip region test element, and a test element 112 arranged in the scribe lane region SCR of the plurality of test elements 112 may be referred to as a second test element 112-2, or a scribe lane test element. It will be understood that, although the terms first, second, third etc. may be used herein to describe various elements, components, regions, layers and/or sections, these elements, components, regions, layers and/or sections should not be limited by these terms. Unless the context indicates otherwise, these terms are only used to distinguish one element, component, region, layer or section from another element, component, region, layer or section, for example as a naming convention. Thus, a first element, component, region, layer or section discussed below in one section of the specification could be termed a second element, component, region, layer or section in another section of the specification or in the claims without departing from the teachings of the present invention. In addition, in certain cases, even if a term is not described using “first,” “second,” etc., in the specification, it may still be referred to as “first” or “second” in a claim in order to distinguish different claimed elements from each other. The test elements described herein can be formed in or on the substrate 102.

The first test elements 112-1 are arranged inside the element region CR. Some of the first test elements 112-1 may not be electrically connected to any test pad 114 arranged in a pad region PR of the scribe lane region SCR. Others of the first test elements 112-1 may be electrically connected to test pads 114 arranged in a pad region PR of the scribe lane region SCR. In addition, the second test elements 112-2 arranged in the scribe lane region SCR may be electrically connected to some test pads 114 arranged in the pad region PR. The first test elements 112-1 may not be electrically connected to the outside of the semiconductor device 100. For example, one or more insulating layers may be arranged on the lowermost layer of the semiconductor chip SC and/or the uppermost layer of the semiconductor chip SC or on side surfaces of the semiconductor chip after singulation, to prevent an electrical connection between the first test element 112-1 and the outside of the semiconductor device 100.

A test signal for testing a test element 112 may be applied through a test pad 114. Accordingly, the test element 112 and the test pad 114 being used for a test procedure may be electrically connected to each other. As used herein, components described as being “electrically connected” are configured such that an electrical signal can be transferred from one component to the other (although such electrical signal may be attenuated in strength as it is transferred and may be selectively transferred). Moreover, components that are “directly electrically connected” share a common electrical node through electrical connections by one or more conductors, such as, for example, wires, pads, internal electrical lines, through vias, etc. As such, directly electrically connected components do not include components electrically connected through active elements, such as transistors or diodes. The test pad 114 may be made of, for example, metal, metal nitride, and/or a combination thereof. In some embodiments, prior to singulation, at least one of the test pads 114 is simultaneously connected to test elements 112 (e.g., first test elements 112-1) of a plurality of element regions CR. A further discussion of this can be seen in connection with FIG. 2B.

For example, test pads 114 may be arranged in the scribe lane region SCR. In some embodiments, both before and after singulation, the test pads 114 may not be arranged inside the element region CR. Accordingly, in some embodiments, the test pads 114 are arranged only in the scribe lane region SCR, and not in the element region CR. For example, according to some embodiments, no test pads are formed in the element region CR at the same vertical height as test pads spaced apart from the element region and formed in the scribe lane region SCR. A region in which test pads 114 are arranged may be referred to as a pad region PR. For example, the pad region PR may be arranged only in the scribe lane region SCR.

For example, each test pad 114 may have a square shape as shown in FIGS. 1 and 2. In another embodiment, the test pads 114 may have a shape of a rectangle, a rhombus, a circle, and/or an ellipse. Since the semiconductor device 100 is cut along the scribe lane region SCR of the substrate 102, the test pads 114 after singulation may be arranged so that a width of the first horizontal direction (X direction) differs from a width of the second horizontal direction (Y direction). For example, during cutting of the wafer, a portion of each test pad 114 may be cut, and each test pad may be split into two separate pieces on two separate singulated semiconductor chips. As a result, for example, the test pads 114 may be arranged in a rectangular shape in which the width in one direction (e.g., the first direction) along the main edge extension direction of the semiconductor chip SC is greater than the width in the second direction perpendicular to the first direction.

In the disclosure, a horizontal direction (X direction and/or Y direction) may refer to a direction parallel to a main surface of the substrate 102, and a vertical direction (Z direction) may refer to a direction perpendicular to the horizontal direction (X direction and/or Y direction).

The test wiring 116 may provide an electrical path so that the test elements 112 electrically connect to corresponding test pads 114, respectively. For example, the test wiring 116 may include or be formed of copper and/or aluminum. The test wiring 116 may be arranged inside the pad region PR and/or inside the element region CR, and may extend from the pad region to the element region. Accordingly, in some embodiments, although test pads 114 are not arranged inside the element region CR, the elements 112 and/or the test wiring 116, for example electrically connected to test pads 114 outside the element region CR, may be arranged inside the element region CR. This will be described in more detail below in connection with FIG. 2B.

The guard ring 120 may be arranged in the element region CR along an edge of the element region CR. The guard ring 120 may have a shape integrally extending without being cut (e.g., a closed loop shape). The guard ring 120 may not be arranged on the uppermost layer of the semiconductor chip SC. The guard ring 120 may include, for example, a plurality of metal vias stacked in a vertical direction (Z direction). For example, the guard ring 120 may have a constant vertical height throughout its circumference and may extend along the edge of the element region CR inside the element region CR. On the other hand, a top surface of the guard ring 120 is flat. From a plan perspective, each of a plurality of first test elements 112-1 may be located inside a horizontal space defined by the guard ring 120. In another embodiment, from a plan perspective, each of the plurality of first test elements 112-1 may be located outside the horizontal space defined by the guard ring 120. Although in FIG. 1, the guard ring is shown as continuously connected in the horizontal direction (X direction and/or Y direction), the guard ring may include a plurality of vias separated in the horizontal direction (X direction and/or Y direction).

In a general semiconductor device, a test pad is arranged inside the element region and inside the pad region. Therefore, an additional process is required to place the test pad inside the element region.

In the semiconductor device 100 of this embodiment, the test pads 114 are arranged only inside the pad region PR, so that a process of forming the test pads 114 may be facilitated. A more detailed explanation of example connections between test pads 114 and test elements 112 will now be discussed in connection with FIG. 2B.

As shown in FIG. 1 and FIG. 2B, according to some embodiments, test pads 114 formed in the scribe lane region SCR may be electrically connected to a first chip region test element 112-1A in an element region CR of a first semiconductor chip, a second chip region test element 112-1B in an element region CR of a second semiconductor chip, a first scribe lane test element 112-2A in a scribe lane region SCR of the first semiconductor chip, and a second scribe lane test element 112-2B in a scribe lane region SCR of the second semiconductor chip. In some embodiments, the first scribe lane test element 112-2A and second scribe lane test element 112-2B may each be between the two test pads 114 in the Y direction that they are connected to, such that during cutting, the first scribe lane test element 112-2A and second scribe lane test element 112-2B are cut through.

As shown in FIG. 2B, each test pad 114 may be connected to one chip region test element 112-1 and one scribe lane test element 112-2, so that each test pad 114 can be used to test both a test element in an element region CR and a test element in a scribe lane region SCR. In this manner, test pads in the element region CR are not needed, because the test pads 114 in the scribe lane region SCR can be used for testing test elements in the element region. A first test wiring 116-1A, second test wiring 116-1B, third test wiring 116-2A, and fourth test wiring 116-2B may be used to connect the test pads 114 to the test elements 112-1A, 112-1B, 112-2A, and 112-2B. For example a first test pad 114-1 and second test pad 114-2 can be connected to the first scribe lane test element 112-2A through third test wiring 116-2A, a third test pad 114-3 and fourth test pad 114-4 can be connected to the second scribe lane test element 112-2B, through fourth test wiring 116-2B, a first test pad 114-1 and third test pad 114-3 can be connected to the second chip region test element 112-1B, and a second test pad 114-2 and fourth test pad 114-4 can be connected to the first chip region test element 112-1A through first test wiring 116-1A. Therefore, probes can be connected to the first test pad 114-1 and second test pad 114-2 to test the first scribe lane test element 112-2A, probes can be connected to the third test pad 114-3 and fourth test pad 114-4 to test the second scribe lane test element 112-2B, probes can be connected to the first test pad 114-1 and third test pad 114-3 to test the second chip region test element 112-1B, and probes can be connected to the second test pad 114-2 and fourth test pad 114-4 to test the first chip region test element 112-1A. After singulation, the various test pads 114, and in some cases, the scribe lane test elements 112-2, can be cut through. Subsequently, the remaining portion of test pads 114 on each singulated semiconductor chip can be covered with an insulating material to prevent electrical access thereto and to electrically isolate the chip region test elements 112-1 from outside of the semiconductor chip.

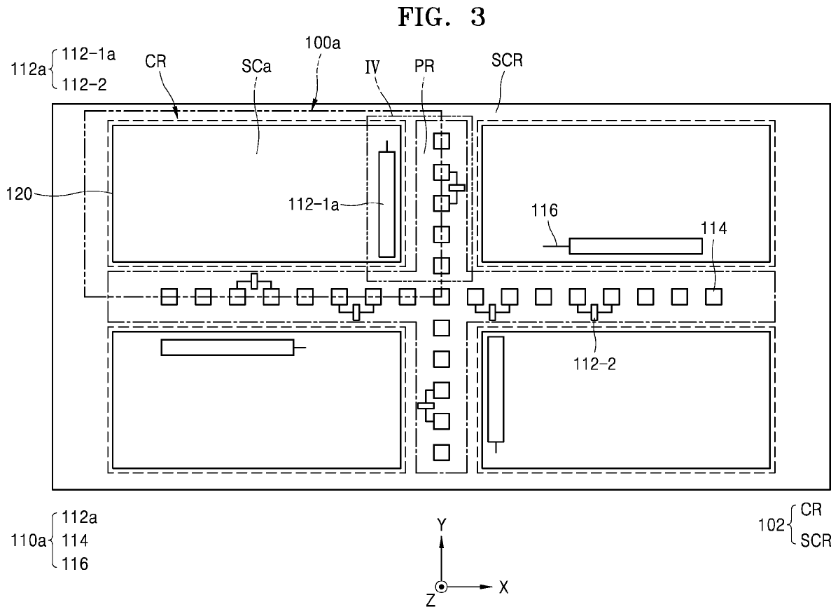

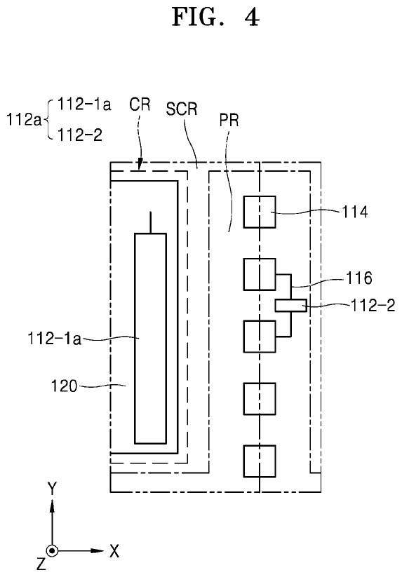

FIG. 3 is a plan layout of a semiconductor device including a test element group according to an embodiment. FIG. 4 is an enlarged plan layout of a portion IV of FIG. 3 according to an embodiment.

Referring to FIGS. 3 and 4, a semiconductor device 100a may include a test element group 110a and a guard ring 120 arranged on a substrate 102. The substrate 102 and the guard ring 120 of FIGS. 3 and 4 may include the same structure and components of the substrate 102 and the guard ring 120 of FIGS. 1 and 2A and 2B other than the test element group 110a, and here, only the test element group 110a will be described below.

The test element group 110a may include a plurality of test elements 112a, a plurality of test pads 114, and a test wiring 116. The test elements 112a may include a first test element 112-1a and a second test element 112-2. For example, the first test element 112-1a may have a rectangular structure in which a width in the second horizontal direction (Y direction) is greater than a width in the first horizontal direction (X direction). For example, the width of the first test element 112-1a in the second horizontal direction (Y direction) may be greater than about two, three, or four times the width of the test pad 114 in the first horizontal direction (X direction). The shape of the first test element 112-1a is an example, and in another embodiment, the first test element 112-1a may have a rectangular structure in which a width of the first horizontal direction (X direction) is greater than a width of the second horizontal direction (Y direction). For example, in some embodiments, the first test element 112-1a may overlap three or more test pads 114 in the first horizontal direction (X direction) and/or the second horizontal direction (Y direction).

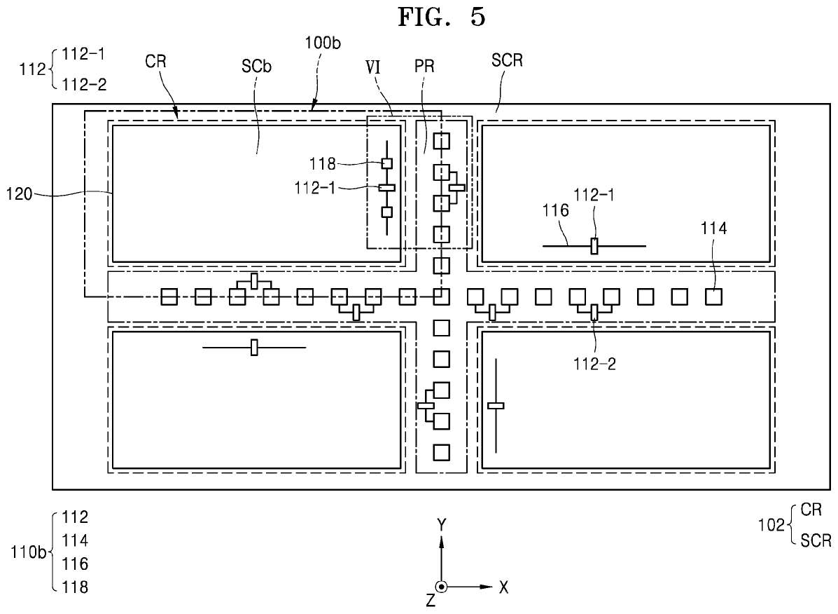

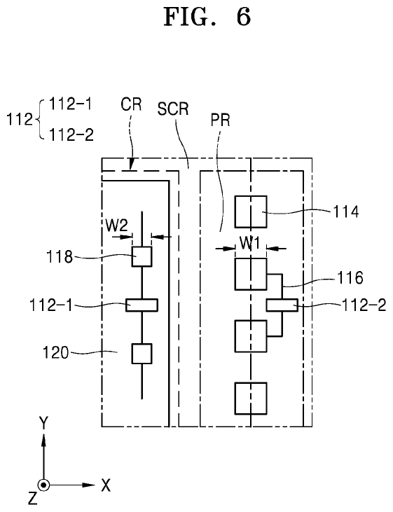

FIG. 5 is a plan layout of a semiconductor device including a test element group according to an embodiment. FIG. 6 is an enlarged plan layout of a portion VI of FIG. 5 according to an embodiment.

Referring to FIGS. 5 and 6, a semiconductor device 100b may include a substrate 102, and a test element group 110b and a guard ring 120, which are arranged on the substrate 102. The substrate 102 and the guard ring 120 of FIGS. 5 and 6 may include the same structure and components as the substrate 102 and the guard ring 120 of FIGS. 1 and 2A and 2B other than the test element group 110b, and here, only the test element group 110b will be described below.

The test element group 110b may include a plurality of test elements 112, a plurality of first pads 114, a plurality of test wirings 116, and a plurality of second pads 118. The first pads 114 of FIGS. 5 and 6 may be the same as or similar to the test pad 114 of FIGS. 1 to 4. The second pad 118 may be referred to as an auxiliary pad 118.

The second pad 118 may cover a top surface of the plurality vias and/or a bottom surface of the plurality vias for protection. The second pads 118 may be pads arranged inside the element region CR. The second pads 118 may be formed at the same vertical height as the first pad 114. The second pads 118 and the test wiring 116 arranged inside the element region CR may be connected to each other, and may be connected to test elements 112-1 in the element region CR. The first pad 114 may be electrically connected to the test element 112-2 in the scribe area SCR, but not to the test element 112-1 in the element area CR. The horizontal area of the second pad 118 may be different from the horizontal area of the first pad 114, at least prior to the first pad 114 being cut during singulation. For example, the horizontal area of the second pad 118 may be smaller than the horizontal area of the first pad 114. For example, the second pad 118 may be so small that circuit inspection (an EDS test) inside the semiconductor chip and semiconductor device inspection of the semiconductor device 100b are impossible. For example, the second pad 118 may have a horizontal area which the test probe cannot contact to perform an inspection. For example, the horizontal width of the test probe may be about 10 micrometers. The width of the edges of the first pad 114 in the first horizontal direction (X direction) may be different from the width of its edges in the second horizontal direction (Y direction). For example, at least one edge (e.g., the relatively long edge) of the edges of the first pad 114 may have a first horizontal width W1. The first horizontal width W1, which is a width of the first horizontal direction (X direction) and/or the second horizontal direction (Y direction), may range from about 20 micrometers to about 60 micrometers. Also, the second horizontal width W2, which is a width in the first horizontal direction (X direction) and/or the second horizontal direction (Y direction) of the second pad 118, may be in a range of about 10 micrometers or less. For example, at least one edge of the edges of the first pad 114 may be greater than the second horizontal width W2 of the second pad 118. When the range of the horizontal width of the test probe changes, the first horizontal width W1 of the first pad 114 and the second horizontal width W2 of the second pad 118 may also change. Therefore, in a first horizontal direction, at least one edge of each of the first pads 14 is longer than the length of each edge of each of the one or more second pads 118.

The second pad 118 may include the same material as the first pad 114. For example, the second pad 118 may be a metal such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), ruthenium (Ru), or an alloy thereof, but is not limited thereto. In another embodiment, the second pad 118 may include a material that is different from that of the first pad 114.

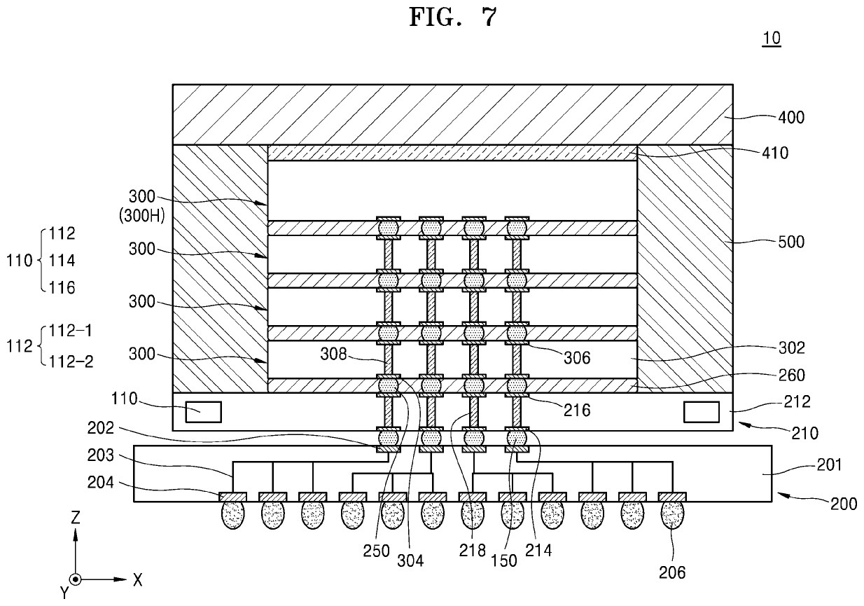

FIG. 7 is a layout diagram illustrating an arrangement of components of a semiconductor package according to an embodiment of the inventive concept.

Referring to FIGS. 1 and 7, the semiconductor package 10 of the present embodiment may include an interposer 200, a first semiconductor chip 210 arranged on the interposer 200, a plurality of second semiconductor chips 300 arranged on the first semiconductor chip 210, and a heat dissipation structure 400 arranged on the second semiconductor chip 300. The first semiconductor chip 210 or one or more of the second semiconductor chips 300 may be the semiconductor chips SC, SCa, and SCb described with reference to FIGS. 1 to 6.

In FIG. 7, one semiconductor package 10 has been illustrated to include one first semiconductor chip 210 and four second semiconductor chips 300, but is not limited thereto. For example, the semiconductor package 10 may include a plurality of first semiconductor chips 210 and/or three or less or five or more second semiconductor chips 300. For example, the semiconductor package 10 may include more than four second semiconductor chips 300. The plurality of second semiconductor chips 300 may be sequentially arranged on the first semiconductor chip 210 in a vertical direction (Z direction). Each of the first semiconductor chip 210 and the plurality of second semiconductor chips 300 may be sequentially stacked while the active surface thereof faces downward, toward the interposer 200.

The interposer 200 may be a printed circuit board (PCB) including a plurality of package substrate pads. However, the interposer 200 is not limited to the structure and material of a PCB, and may include various types of substrates. The interposer 200 may include a base layer 201, and a plurality of interposer top pads 202 and a plurality of interposer bottom pads 204 arranged on the top and bottom surfaces of the base layer 201, respectively. The interposer 200 may include a plurality of wiring paths 203 electrically connecting the plurality of interposer top pads 202 with the plurality of interposer bottom pads 204 through the base layer 201. The horizontal area of the interposer 200 may have a value larger than a footprint occupied by each of the first semiconductor chip 210 and the plurality of second semiconductor chips 300.

In some embodiments, the base layer 201 may include a semiconductor material, glass, ceramic, or plastic. In some embodiments, the interposer 200 may be a silicon interposer in which the base layer 201 is formed from a silicon semiconductor substrate. In another embodiment, the interposer 200 may be a redistribution layer (RDL) interposer.

The plurality of interposer top pads 202 and the plurality of interposer bottom pads 204 may include or may be formed of copper, nickel, stainless steel, or copper alloys such as beryllium copper.

In some embodiments, the plurality of wiring paths 203 may include a plurality of interposer through electrodes vertically penetrating at least a portion of the base layer 201. The plurality of interposer through electrodes may electrically connect the plurality of interposer top pads 202 with the plurality of interposer bottom pads 204. Each of the plurality of interposer through electrodes may include a conductive plug through the base layer 201 and a conductive barrier layer surrounding the conductive plug. The conductive plug may have a cylindrical shape, and the conductive barrier layer may have a cylindrical shape surrounding a sidewall of the conductive plug. A plurality of via insulating layers may be placed between the base layer 201 and the plurality of interposer through electrodes to surround sidewalls of the plurality of interposer through electrodes.

A plurality of package connection terminals 150 are connected to the plurality of interposer top pads 202, and a plurality of external connection terminals 206 may be connected to the plurality of interposer bottom pads 204. The plurality of package connection terminals 150 may electrically connect the interposer 200 with the first semiconductor chip 210. The plurality of external connection terminals 206 connected to the plurality of interposer bottom pads 204 may connect the semiconductor package 10 to the outside.

In some embodiments, the plurality of package connection terminals 150 may be formed of a conductive material, such as copper (Cu), aluminum (Al), silver (Ag), tin (Sn), gold (Au), or solder, but they are not limited thereto. The plurality of package connection terminals 150 may be formed of multiple layers or a single layer. For example, each of the plurality of package connection terminals 150 may include an under bump metallurgy (UBM) layer and an interposer conductive cap on the UBM layer.

In some embodiments, the first semiconductor chip 210 may not include a memory cell. The first semiconductor chip 210 may include a serial-parallel conversion circuit, a design for test (DFT), a test logic circuit such as a joint test action group (JTAG), a memory built-in self-test (MBIST), and a signal interface circuit such as a physical layer (PHY). The plurality of second semiconductor chips 300 may include memory cells. For example, the first semiconductor chip 210 may be a buffer chip for controlling the plurality of second semiconductor chips 300.

The plurality of second semiconductor chips 300 may be a volatile memory such as a DRAM, a SRAM, or a Vertical Couple Transistor (VCT) Dynamic Random Access Memory DRAM, a Non-Volatile Memory such as PRAM, MRAM, a Ferroelectric Random Access Memory (FeRAM), or RRAM. Here, the VCT DRAM may refer to a structure in which a channel length of the channel layer extends in a vertical direction from the substrate.

In some embodiments, the first semiconductor chip 210 may be a buffer chip for controlling a high bandwidth memory (HBM) DRAM, and the plurality of second semiconductor chips 300 may be memory cell chips having cells of the HBM DRAM controlled by the first semiconductor chip 210. The first semiconductor chip 210 may be referred to as a buffer chip or a master chip, and the plurality of second semiconductor chips 300 may be referred to as slave chips or memory cell chips. The first semiconductor chip 210 and the plurality of second semiconductor chips 300 stacked on the first semiconductor chip 210 may be referred to as HBM DRAM elements, together.

The first semiconductor chip 210 and/or the second semiconductor chips 300 may include a test element 112 and 112a, a test wiring 116, and/or a guard ring 120 of FIGS. 1 to 6. The test element 112 and 112a may include a first test element 112-1 and 112-1a arranged in an element region of the first semiconductor chip 210 and a second test element 112-2 arranged in a scribe lane region of the first semiconductor chip 210. The guard ring 120 is arranged along an edge of the first semiconductor chip 120, and the test elements 112 and 112a are spaced apart from the guard ring 120 in the horizontal direction (X direction and/or Y direction). The guard ring 120 may be arranged to have a constant vertical height.

In one embodiment, the test element 112 and 112a, the test wiring 116, and/or the guard ring 120 of the first semiconductor chip 210 does not overlap the plurality of second semiconductor chips 300 in a vertical direction (Z direction). For example, when viewed in a plan view, the test element 112 and 112a, the test wiring 116, and/or the guard ring 120 of the first semiconductor chip 210 may be arranged on a portion extending outward in a horizontal direction (X-direction and/or Y-direction) of a position corresponding to the plurality of second semiconductor chips 300. For example, when viewed in a plan view, the test element group 110, 110a and 110b of the first semiconductor chip 210 may be arranged on a portion expanded to the outside in a horizontal direction (X-direction and/or Y-direction) of a position corresponding to the plurality of second semiconductor chips 300.

The first test element 112-1 and 112-1a arranged in the first semiconductor chip 210 may not be electrically connected to the interposer 200 and/or the plurality of second semiconductor chips 300. In another embodiment, although not shown, auxiliary pads 118 of FIG. 5 may be arranged inside the first semiconductor chip 210. When the test element 112 and the auxiliary pad 118 of FIG. 5 are arranged on the first semiconductor chip 210, the first test element 112-1 arranged on the first semiconductor chip 210 may be electrically connected to the interposer 200 and/or each of the plurality of second semiconductor chips 300.

In some embodiments, the upper surface of the first semiconductor chip 210 may be positioned at a vertical level higher than the upper surface of the guard ring 120. For example, the lower surface of the first semiconductor chip 210 may be located at a lower vertical level than the lower surface of the guard ring 120. Insulating layers are arranged on the upper and lower surfaces of the guard ring 120 to electrically insulate the test element group 110, 110a and 110b.

The first semiconductor chip 210 includes a first substrate 212, a plurality of first front connection pads 214, a plurality of first rear connection pads 216, and a plurality of first through electrodes 218. The second semiconductor chip 300 includes a second substrate 302, a plurality of second front connection pads 304, a plurality of second rear connection pads 306, and a plurality of second through electrodes 308.

The first and second substrates 212 and 302 may include or be formed of silicon (Si). Alternatively, the first and second substrates 212 and 302 may include semiconductor elements such as germanium (Ge), or compound semiconductors such as silicon carbide (SiC), gallium arsenide (GaAs), indium arsenide (InAs), and indium phosphide (InP). The first and second substrates 212 and 302 may have an active surface and an inactive surface opposite to the active surface.

The first and second substrates 212 and 302 may include a plurality of different types of individual devices on the active surfaces thereof. The plurality of individual devices may include various microelectronic devices such as a MOSFET such as a CMOS) transistor, an image sensor such as an LSI, a CIS, etc., a micro-electro-mechanical system (EMS), an active device and/or a passive device, etc.

The first and second semiconductor devices may be formed on the active surfaces of the first and second substrates 212 and 302, and the plurality of first and second front connection pads 214 and 304 and the plurality of first and second rear connection pads 216 and 306 may be arranged on the active and inactive surfaces of the first and second substrates 212 and 302, respectively.

The plurality of first and second through electrodes 218 and 308 may vertically penetrate at least a portion of the first and second substrates 212 and 302 to electrically connect the plurality of first and second front connection pads 214 and 304 with the plurality of first and second rear connection pads 216, 306.

A plurality of chip connection terminals 250 may be attached to the plurality of second front connection pads 304 of the second semiconductor chip 300. The plurality of chip connection terminals 250 may be placed between the plurality of first rear connection pads 216 of the first semiconductor chip 210 and the plurality of second front connection pads 304 of the second semiconductor chip 300, and/or between the second front connection pad 304 and the second rear connection pad 306, to electrically connect the first semiconductor chip 210 with the second semiconductor chip 300.

In some embodiments, among the plurality of second semiconductor chips 300, a second semiconductor chip 300H positioned at the uppermost end farthest from the first semiconductor chip 210 may not include the second rear connection pad 306 and the second through electrode 308.

Insulating adhesive layers 260 may be placed between the first semiconductor chip 210 and the lowermost second semiconductor chips 300 and/or between each of the plurality of second semiconductor chips 300. The insulating adhesive layer 260 may be attached to the bottom surface of each of the plurality of second semiconductor chips 300 to connect the plurality of second semiconductor chips 300 to each other. The insulating adhesive layer 260 may include a nonconductive film (NCF), a nonconductive paste (NCP), an insulating polymer, or an epoxy resin. The insulating adhesive layer 260 may surround the chip connection terminal 250 and fill a gap between the plurality of second semiconductor chips 300. In another embodiment, the insulating adhesive layer 260 may fill a gap between the first semiconductor chip 210 and the lowermost plurality of second semiconductor chips 300 and/or between each of the plurality of second semiconductor chips 300.

A portion of each of the first semiconductor chips 210 may protrude from an outer surface of the plurality of second semiconductor chips 300. For example, all the plurality of second semiconductor chips 300 may overlap the first semiconductor chip 210 in a vertical direction (Z direction).

The heat dissipation structure 400 may be arranged on the plurality of second semiconductor chips 300. The thickness of the heat dissipation structure 400 may be greater than the thickness of each of the first semiconductor chip 210 and the second semiconductor chips 300. When the thickness of the heat dissipation structure 400 is increased, heat of the semiconductor package 10 may be better discharged.

The heat dissipation structure 400 may be formed of a semiconductor material. For example, the heat dissipation structure 400 may include silicon (Si). Alternatively, the heat dissipation structure 400 may include a semiconductor elements such as germanium (Ge), or a compound semiconductor such as SiC, GaAs, InAs, and InP. For example, the heat dissipation structure 400 may be made of the same material as the first substrate 212.

The heat dissipation structure 400 may be formed of a material having higher thermal conductivity than the first semiconductor chip 210 and the second semiconductor chips 300. For example, the heat dissipation structure 400 may include copper. For example, the heat dissipation structure 400 may include electro-plating copper (Cu). The electroplating copper may be formed as a metal coating on the heat dissipation structure 400 by electrolysis.

The heat dissipation structure 400 may be formed of a plurality of layers. The plurality of layers may be formed of the same material or may be formed of different materials. Of course, the material of the heat dissipation structure 400 is not limited to copper. For example, the heat dissipation structure 400 may be formed of a metal having good thermal conductivity. For example, the heat dissipation structure 400 may include metal such as nickel (Ni), gold (Au), silver (Ag), aluminum (Al), tungsten (W), titanium (Ti), tantalum (Ta), indium (In), molybdenum (Mo), manganese (Mn), cobalt (Co), tin (Sn), magnesium (Mg), rhenium (Ru), beryllium (Be), gallium (Ga), ruthenium (Ru), etc., or alloys thereof.

According to an embodiment of the inventive concept, the uppermost second semiconductor chip 300H and the heat dissipation structure 400 may be bonded to each other by a thermal interface material (TIM) 410.

A method of manufacturing a semiconductor device may include the following. First, the substrate 102 including the element regions CR and the scribe lane regions SCR may be prepared. Then, the test element 112 may be formed in the element regions CR and the test pad 114 may be formed in the scribe lane area SCR. Then, the test element 112 and the test pad 114 may electrically connect by test wiring 116. A test signal may be applied to the test element 112 through the test pad 114. Thereafter, the test wiring 116 may be electrically disconnected. Therefore, test element 112 in the element regions CR and the test pad 114 in the scribe lane area SCR may be electrically separated. After a test process of the test element 112, subsequent semiconductor processes may be performed. For example, the subsequent semiconductor processes may include a singulation process for individualizing the substrate 102 into respective semiconductor chips, and a packaging process for packaging the semiconductor chips. By performing the subsequent semiconductor processes on the substrate 102, the semiconductor device may be completed.

The semiconductor package 10 may further include the molding layer 500 surrounding the plurality of second semiconductor chips 300 on the first semiconductor chip 210. The molding layer 500 may be formed of, for example, an epoxy mold compound (EMC). In some embodiments, the molding layer 500 may cover the side surfaces of the plurality of second semiconductor chips 300, the side surfaces of the insulating adhesive layer, and the top surface of the uppermost second semiconductor chip 300H together.

In some embodiments, the molding layer 500 may cover the side surfaces of the plurality of second semiconductor chips 300, but may not cover the side surfaces of the heat dissipation structure 400. For example, the lower surface of the heat dissipation structure 400 and the upper surface of the molding layer 500 may be in substantially the same plane. According to an embodiment of the inventive concept, the side surfaces of the molding layer 500 may be substantially coplanar with the side surfaces of the first semiconductor chip 210.

For example, it has been described that the semiconductor devices 100, 100a, and 100b and/or the semiconductor chips SC, SCa, and SCb of FIGS. 1 to 6 form an HBM device, but the technical idea of the present disclosure is not limited thereto. For example, it goes without saying that the semiconductor devices 100, 100a, and 100b and/or semiconductor chips SC, SCa, and SCb of FIGS. 1 to 6 may be used in correspondence to various form factors.

While the inventive concept has been particularly shown and described with reference to embodiments thereof, it will be understood that various changes in form and details may be made therein without departing from the spirit and scope of the following claims.

Terms such as “same,” “equal,” “planar,” or “coplanar,” as used herein when referring to orientation, layout, location, shapes, sizes, compositions, amounts, or other measures do not necessarily mean an exactly identical orientation, layout, location, shape, size, composition, amount, or other measure, but are intended to encompass nearly identical orientation, layout, location, shapes, sizes, compositions, amounts, or other measures within acceptable variations that may occur, for example, due to manufacturing processes. The term “substantially” may be used herein to emphasize this meaning, unless the context or other statements indicate otherwise. For example, items described as “substantially the same,” “substantially equal,” or “substantially planar,” may be exactly the same, equal, or planar, or may be the same, equal, or planar within acceptable variations that may occur, for example, due to manufacturing processes. Terms such as “about” or “approximately” may reflect amounts, sizes, orientations, or layouts that vary only in a small relative manner, and/or in a way that does not significantly alter the operation, functionality, or structure of certain elements. For example, a range from “about 0.1 to about 1” may encompass a range such as a 0%-5% deviation around 0.1 and a 0% to 5% deviation around 1, especially if such deviation maintains the same effect as the listed range.

1. A semiconductor device comprising:
a substrate including an element region and a scribe lane region defining and surrounding the element region; and
one or more test circuits arranged on the substrate and including one or more test elements for characteristic evaluation and one or more test pads for applying a test signal for testing the one or more test elements,
wherein all of the one or more test pads are spaced apart from the element region in a horizontal direction.

2. The semiconductor device of claim 1, wherein the one or more test elements are arranged in the element region.

3. The semiconductor device of claim 1, wherein at least a first test pad of the one or more test pads is electrically connected to a first test element of the one or more test elements, the first test element formed in the element region.

4. The semiconductor device of claim 3, wherein the first test pad is electrically connected to the first test element and to a second test element formed in the scribe lane region.

5. The semiconductor device of claim 1, wherein each of the one or more test pads is arranged to have a first horizontal direction width in a first horizontal direction that differs from a second horizontal direction width in a second horizontal direction.

6. The semiconductor device of claim 5, wherein a relatively longer horizontal width between the first horizontal direction width and the second horizontal direction width of at least one test pad of the one or more test pads ranges from about 20 micrometers to about 60 micrometers.

7. The semiconductor device of claim 1, further comprising a guard ring arranged along an edge of the element region inside the element region.

8-10. (canceled)

11. A semiconductor device comprising:
a substrate including an element region and a scribe lane region defining and surrounding the element region; and
one or more test element circuits arranged on the substrate and including one or more test elements for characteristic evaluation and one or more first test pads electrically connected to first test elements of the one or more test elements and for applying a test signal for testing the one or more test elements, wherein:
all of the one or more first test pads are arranged in a pad region outside of the element region in a horizontal direction,
the one or more test elements include one or more first test elements, arranged in the scribe lane region and one or more second test elements arranged in the element region,
the one or more test element circuits further include one or more second pads arranged in the element region and electrically connected to the one or more respective second test elements,
the one or more second pads are formed at the same vertical height as the one or more first test pads, and
in a first horizontal direction, at least one edge of each of the one or more first test pads is longer than the length of each edge of each of the one or more second pads.

12. The semiconductor device of claim 11, wherein each of the one or more first test pads has a horizontal area that is sufficient to allow testing by a test probe having a particular size, and each of the one or more second pads has a horizontal area that is insufficient to enable test probe having the particular size.

13. The semiconductor device of claim 11, wherein horizontal widths of the one or more second pads are in a range of about 10 micrometers or less.

14. The semiconductor device of claim 11, wherein,
in each of the one or more first test pads, a length of an edge in the first horizontal direction differs from a length of an edge in a second horizontal direction, and
a length of a relatively long edge of each of the one or more first test pads ranges from about 20 micrometers to about 60 micrometers.

15. The semiconductor device of claim 11, wherein each of the one or more second pads is formed of the same material as the one or more first test pads.

16. The semiconductor device of claim 11, wherein each of the one or more second pads includes a material that is different from that of the one or more first test pads.

17. The semiconductor device of claim 11, wherein the one or more first test pads are not electrically connected to the one or more second test elements.

18. The semiconductor device of claim 11, further comprising:
a guard ring arranged along the edge of the element region in the element region, wherein,
from a plan perspective, the guard ring surrounds the one or more first test elements.

19-21. (canceled)

22. A semiconductor package comprising:
an interposer;
a first semiconductor chip arranged on the interposer and including an element region and a scribe lane region defining and surrounding the element region;
a plurality of second semiconductor chips sequentially stacked on the first semiconductor chip,
a molding layer surrounding the plurality of second semiconductor chips on the first semiconductor chip; and
one or more test element groups arranged on the first semiconductor chip and including one or more test elements for characteristic evaluation and one or more test pads for applying a test signal for testing the one or more test elements,
wherein the one or more test pads are spaced apart from the element region in a horizontal direction, and
wherein at least a first test pad of the one or more test pads is electrically connected to a first test element of the one or more test elements, the first test element formed in the element region.

23. The semiconductor package of claim 22, wherein, from a plan perspective, the one or more test element groups do not overlap the plurality of second semiconductor chips in a vertical direction.

24. The semiconductor package of claim 22, wherein the one or more test elements are arranged in the element region of the first semiconductor chip and are not electrically connected to the plurality of second semiconductor chips or the interposer.

25. The semiconductor package of claim 22, further comprising:
a guard ring arranged along an edge of the first semiconductor chip, wherein:
the one or more test elements and the guard ring are spaced apart from each other in a horizontal direction.

26. The semiconductor package of claim 25, wherein the guard ring is arranged to have a constant vertical height.
